(19) United States
(12) Patent Application Publication
(10) Pub. No.: US 2026/0211211 A1
(43) Pub. Date: Jul. 23, 2026

(54) SECURING DEVICE

(71) Applicant: Carl Zeiss SMT GmbH, Oberkochen (DE)

(72) Inventor: Eugen ANSELM, Aalen (DE)

(21) Appl. No.: 19/535,526

(22) Filed: Feb. 10, 2026

Related U.S. Application Data
(63) Continuation of application No. PCT/EP2024/073255, filed on Aug. 20, 2024.

(30) Foreign Application Priority Data
Aug. 23, 2023 (DE) 10 2023 208 042.7

(51) Int. Cl. G02B 7/18; G02B 7/182; G03F 7/00

(52) U.S. Cl. CPC G02B 7/181; G02B 7/182; G03F 7/70833; G03F 7/70891

(57) ABSTRACT

A fastening device for fastening a functional component to a substrate body comprises: a functional component, which is insertable into a receptacle in the substrate body; and a fastening component comprising at least two clamping elements for establishing a form-fitting connection between the functional component and the substrate body.

### CROSS-REFERENCE TO RELATED APPLICATIONS

The present application is a continuation of, and claims benefit under 35 USC 120 to, international application No. PCT/EP2024/073255, filed Aug. 20, 2024, which claims benefit under 35 USC 119 of German Application No. 10 2023 208 042.7, filed Aug. 23, 2023. The entire disclosure of each of these applications is incorporated by reference herein.

### FIELD

The present disclosure relates to a fastening device for fastening a functional component to a substrate body. The disclosure also relates to a mirror apparatus having such a fastening device, to an optical system having such a mirror apparatus and to a projection exposure apparatus having such an optical system.

### BACKGROUND

Mirror substrates and functional components connected thereto are known through prior use.

Fastening devices are known from CA 2 624 761 A1, CN 114 321 112 A, WO 2004/088 154 A1, US 2008/0078031 A1 and DE 102 13 214 A1.

### SUMMARY

The disclosure seeks to provide a fastening device which facilitates the fastening of a functional component to a substrate body and which, for example, makes it relatively easy to work with, especially in the case of sensitive materials, e.g. brittle materials, for the substrate body.

According to an aspect, the disclosure provides a fastening device for fastening a functional component to a substrate body. The fastening device has the functional component, which is insertable into a receptacle in the substrate body. The fastening device also has a fastening component having at least two clamping elements for establishing a form-fitting connection between, firstly, the functional component and, secondly, the fastening component and the substrate body. A volumetric coefficient of thermal expansion of the functional component is lower than a volumetric coefficient of thermal expansion of the fastening component disclosure.

The disclosure allows for the use of a fastening component in order to fasten the functional component thereto and to the substrate body in a form-fitting manner.

The functional component is arrangeable in a receptacle of the substrate body. The fastening component may likewise be arrangeable in the receptacle of the substrate body. It is also possible for the fastening receptacle to be arrangeable on an outer surface of the substrate body.

The receptacle of the substrate body may be in the form of a blind hole. It is also possible for the receptacle of the substrate body to be in the form of a through-bore. The receptacle may have a central axis, such as an axis of symmetry. For example, the receptacle may be formed rotationally symmetrically with respect to the axis of symmetry.

The fastening component can comprise at least two clamping elements, which are used to realize the form-fitting connection between the functional component and the substrate body.

The functional component may be in the form of a rotationally symmetric body, such as a cylindrical body. It is also possible for the functional component to be in the form of a rectilinear body with an n-fold rotational symmetry.

The functional component may protrude from the receptacle of the substrate body on one side and on both sides for example. It is also possible for the functional component to be arranged entirely within the receptacle of the substrate body.

The functional component can have an axial direction and a radial direction. In the axial direction, the functional component can be arranged at least partially within the receptacle of the substrate body. The radial direction is perpendicular to the axial direction. The extent of the functional component in the radial direction is referred to as the radius of the functional component. The radius of the functional component might not be constant.

The functional component may contain a cavity that extends and can be continuous in the axial direction. For example, the functional component may be configured as a ring-shaped body. In this case, a ring should be understood to be a body whose surface has a topological genus of 1.

The fastening component may be in the form of a rotationally symmetric component part. It is possible for the fastening component to be in the form of a rotationally symmetric component part with an n-fold rotational symmetry. It is possible for the symmetry of the fastening component and the symmetry of the functional component to be matched to each other. It is also possible that neither the fastening component nor the functional component has inherent symmetries.

Fastening a functional component to a substrate body in a form-fitting manner with a fastening component can have a multiplicity of desirable technical features:
A worker can be able to produce such a connection relatively easily, quickly and efficiently as a result of a form-fitting connection being realized by the meshing of the connection partners in accurately fitting fashion for example. It can be possible to dispense with additional connection elements such as screws, nuts or bolts. Moreover, additional fastening steps such screwing, welding and/or adhesive bonding of components can be dispensed with.

A form-fitting connection can be reversibly producible and releasable. This can allow the functional component to be replaced relatively quickly and easily. Using the fastening device according to the disclosure, it can be possible to relatively quickly and relatively flexibly adapt the functional component to the desired properties in each case. Maintenance and/or replacement of the functional component may also be facilitated in the event of possible damage and/or wear of the functional component.

The time- and temperature-dependent viscoelastic or plastic deformation of the connection partners under load, known as “creep”, can also be reduced and for example avoided via the fastening device according to the disclosure.

Furthermore, relatively large tolerances in the dimensioning of the substrate body are still possible as a result of the interaction between the functional component and the fastening component.

The functional component may have a T-shaped cross section. In such a case, the axial direction of the functional component can represent the axis of symmetry of the T-shaped cross section.

The at least two clamping elements of the fastening component can establish a form-fitting connection between the functional component and the substrate body, wherein the clamping elements of the fastening component can mediate the establishment of this form-fitting connection in such a way that the connection is established between, firstly, the functional component and, secondly, the assembly made of fastening component and substrate body.

The functional component and/or the substrate body may be a component of a lithographic projection exposure apparatus for producing structured component parts, for example structured semiconductor component parts.

The functional component may be in the form of an interface by which further component parts, for example electronic component parts or bearing component parts, can be connected to the fastening device.

The fastening device may be part of an optical component, especially of a projection exposure apparatus. This optical component may be a mirror, for example a collector mirror or a mirror of an illumination optics unit in a projection exposure apparatus for guiding used light toward an object field or a mirror in an imaging optical unit in a projection exposure apparatus for imaging an object field into an image field, or else a lens element or else a component—especially in a projection exposure apparatus—which does not serve to guide used light. The mirror may be a grazing incidence mirror (GI mirror; mirror with an angle of incidence greater than 45 degrees) or else a normal incidence mirror (NI mirror; mirror with an angle of incidence of less than 45 degrees). A mirror body of such a mirror, which bears a reflection surface, such as a highly reflective layer or a highly reflective multilayer, may be a main body made of Si or else SiSiC.

To the extent that the functional component is an optical component, it is commonly the component which serves for direct optical beam guidance. An example of a non-optical component, a part of which is the fastening device, is a frame of a detection device. Such a frame may be manufactured from SiSiC. In this case, the functional component can be at least one sensor element. Other examples of non-optical functional components include measuring mechanisms and tools for projection exposure having a main body made of silicon or ceramic, such as SiSiC.

In the fastening device, the volumetric coefficient of thermal expansion of the functional component can be lower than the volumetric coefficient of thermal expansion of the fastening component. This can help avoid undesired stress between the functional component and the fastening component, especially when the fastening device is heated.

In some embodiments, the functional component comprises a functional component bearing surface by which the functional component can be placed against the substrate body. Such embodiments can help ensure a particularly stable connection between the functional component and the substrate body. The functional component can be placed reliably and securely against the substrate body as a result of the functional component bearing surface. This can allow for a more precise introduction of the functional component into the receptacle of the substrate body. The additional contact pressure that arises between the functional component bearing surface and the substrate body can lead to the functional component being held in position in a particularly stable manner.

The functional component bearing surface may have a planar or else curved embodiment.

In the case of a functional component with a T-shaped cross section, the functional component bearing surface may be situated at a boundary surface of a main limb portion of the T-shaped longitudinal section, i.e. for example in that portion of the functional component which has a greater diameter.

In some embodiments, the fastening component is designed to receive the functional component in a centered position in the receptacle of the substrate body. Such embodiments can help allow for relatively high tolerances of the substrate body. The less accurate the production of the substrate body, for example the production of the receptacle of the substrate body, the less precise the form-fitting connection between the functional component and the substrate body. A fastening component configured such that it centers the functional body when the latter can be fastened in the receptacle of the substrate body compensates for these tolerances particularly efficiently.

In some embodiments, the functional component comprises a curved fastening bearing surface with a non-constant radius of curvature, by which the functional component is placed against the clamping element of the fastening component. Such embodiments may be mounted in a particularly simple manner. The non-constant radius of the radial fastening bearing surface of the functional component can result in two possible positions which a functional component may adopt in the receptacle of the substrate body.

The functional component may be arranged in the receptacle of the substrate body in a non-clamped state, i.e. in a non-clamped position. In the non-clamped state, the functional component can be held loosely by the fastening component and has freedom of movement, especially in the radial direction. In the non-clamped state, the functional component can be removed from and/or inserted into the receptacle of the substrate body particularly easily.

Alternatively, the functional component may be arranged in the receptacle of the substrate body in the clamped state, i.e. in the clamped position. In the clamped state, the form fit can be ensured, especially in the radial direction. In the clamped position, the functional component does not have any freedom of movement in the radial direction. In the clamped position, the functional component may be arranged in the receptacle of the substrate body, such as in centered fashion.

In the clamped position, a form fit, or at least a partial form fit, is also generated in the axial direction. Removal of the functional component from and/or insertion of the functional component into the receptacle body is made relatively difficult and for example prevented in the clamped position. As a result, the functional component can be fastened to the substrate body in a particularly secure and stable manner.

In some embodiments, the toothing of the fastening bearing surface of the functional component and/or the ribs of the fastening component that extend opposite to the radial direction have a constant gradient in the circumferential direction. Such embodiments can help enable particularly simple switching of the functional component from the non-clamped state into the clamped state. As a result of the constant gradient of the toothing of the fastening bearing surface of the functional component and/or the constant gradient of the fastening elements of the fastening component which are in the form of ribs that extend opposite to the radial direction, it is possible to insert the functional component into the receptacle of the substrate body in the non-clamped state and secure the functional component via the clamping element of the fastening component by turning said functional component in the circumferential direction.

In this case, the constant gradient of the component parts can help ensure that the force expenditure increases uniformly during such a rotation and/or that the rotational movement is smooth, i.e. without jerk in the physical sense. This can significantly simplify the assembly of the functional component on the substrate body.

In some embodiments, the substrate body represents a constituent part of the fastening device, with the substrate body comprising a receptacle for the functional component. Such embodiments can help enable a particularly secure connection between functional component and substrate body. There can be a particularly high holding force between the two components as a result of wedging and/or clamping the functional component and the fastening component together. The connection between the functional component and the substrate body can be particularly secure and stable as a result.

In some embodiments, the volumetric coefficient of thermal expansion of the functional component is lower than the volumetric coefficient of thermal expansion of the substrate body and/or the volumetric coefficient of thermal expansion of the substrate body is lower than the volumetric coefficient of thermal expansion of the fastening component. Such embodiments can be particularly heat resistant. If the substrate body and consequently also the functional component and/or the fastening component heat up, then these component parts will experience thermal expansion.

In embodiments of the preceding paragraph, the greatest expansion in the process can be experienced by the fastening component. The functional component can expand the least. The expansion of the substrate body can lie between them. This can help to ensure that the thermal expansion results in no further forces acting on the functional component, apart from the desired assembly holding forces between the fastening component and the functional component. Rapid wear of the functional component can be avoided as a result. The fastening device according to the disclosure can help ensure that the functional component has a particularly long service life.

The expansion behavior described in the preceding two paragraphs can also help ensure that the functional component is arranged precisely in the receptacle of the substrate body even under thermal action.

To this end, the functional component may be manufactured from a metal, for example from Invar. Invar has proven its worth for such applications owing to its particularly low coefficient of thermal expansion.

The fastening component may be formed from a further metal, the latter however having a significantly higher coefficient of thermal expansion than Invar. The fastening component may be manufactured from a material such as stainless steel or aluminum.

The substrate body can be formed from silicon carbide, and from silicon-infiltrated silicon carbide (SiSiC) according to an embodiment variant.

The disclosure can provide an improved mirror apparatus, such as an EUV collector, an optical system and a projection exposure apparatus.

In aspects, the disclosure provides a mirror apparatus having at least one fastening device according to the disclosure, an optical system having such a mirror apparatus, and a projection exposure apparatus having such an optical system.

Features of the mirror apparatus, the optical system and the projection exposure apparatus can correspond to those which have already been explained above with reference to the fastening device.

The projection exposure apparatus can be used to produce a microchip made of semiconductor material, such as a memory chip. Such a semiconductor component part, which may be produced by the projection exposure apparatus, may comprise microstructures or nanostructures.

### BRIEF DESCRIPTION OF THE DRAWINGS

Exemplary embodiments of the disclosure are explained in more detail below with reference to the figures, in which:

FIG. 1 schematically shows a meridional section of a projection exposure apparatus for EUV projection lithography;

FIG. 2 shows a fastening device in a longitudinal section; and

FIG. 3 shows a sectional view of the fastening device in accordance with the section line III-III in FIG. 2.

### DETAILED DESCRIPTION

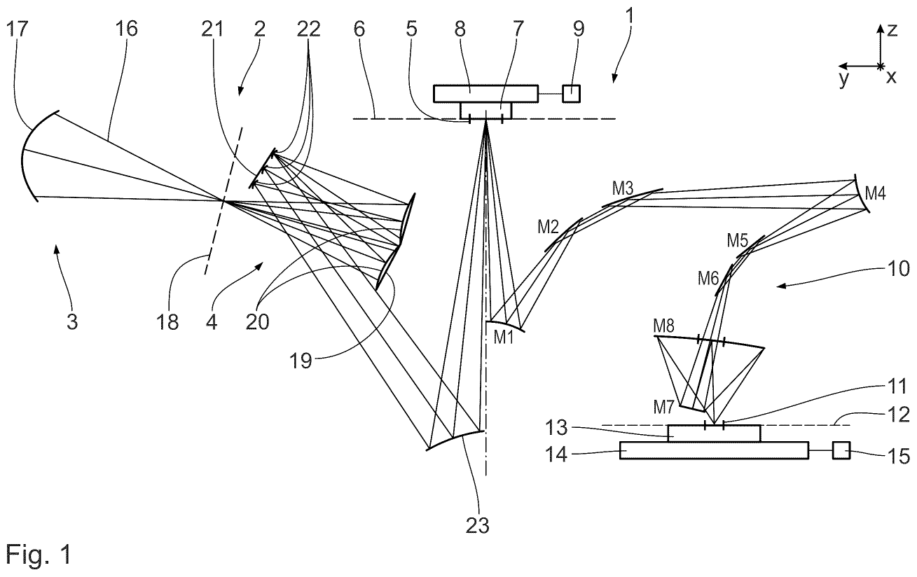

Certain constituent parts of a microlithographic projection exposure apparatus 1 are first described by way of example hereinafter with reference to FIG. 1. The description of the basic set-up of the projection exposure apparatus 1 and the constituent parts thereof should be understood here to be non-limiting.

One embodiment of an illumination system 2 of the projection exposure apparatus 1 has, in addition to a light or radiation source 3, an illumination optics unit 4 for illuminating an object field 5 in an object plane 6. In an alternative embodiment, the light source 3 may also be provided in the form of a module separate from the rest of the illumination system. In this case, the illumination system does not comprise the light source 3.

A reticle 7 arranged in the object field 5 is exposed. The reticle 7 is held by a reticle holder 8. The reticle holder 8 is displaceable for example in a scanning direction by way of a reticle displacement drive 9.

A Cartesian xyz-coordinate system is depicted in FIG. 1 for explanation purposes. The x-direction runs perpendicularly to the plane of the drawing into the latter. The y-direction runs horizontally, and the z-direction runs vertically. The scanning direction runs in the y-direction in FIG. 1. The z-direction runs perpendicularly in relation to the object plane 6.

The projection exposure apparatus 1 comprises a projection optics unit 10. The projection optics unit 10 is used to image the object field 5 into an image field 11 in an image plane 12. The image plane 12 extends parallel to the object plane 6. Alternatively, an angle between the object plane 6 and the image plane 12 that differs from 0° is also possible.

A structure on the reticle 7 is imaged onto a light-sensitive layer of a wafer 13 arranged in the region of the image field 11 in the image plane 12. The wafer 13 is held by a wafer holder 14. The wafer holder 14 is displaceable, for example in the y-direction, by way of a wafer displacement drive 15. The displacement, firstly, of the reticle 7 by way of the reticle displacement drive 9 and, secondly, of the wafer 13 by way of the wafer displacement drive 15 may be synchronized with one another.

The radiation source 3 is an EUV radiation source. The radiation source 3 emits EUV radiation 16, which is also referred to below as used radiation or illumination radiation. The used radiation has for example a wavelength in the range of between 5 nm and 30 nm. The radiation source 3 may be a plasma source, for example a laser-produced plasma (LPP) source or a gas discharge-produced plasma (GDPP) source. It may also be a synchrotron-based radiation source. The radiation source 3 may be a free electron laser (FEL).

The illumination radiation 16 emanating from the radiation source 3 is focused by a collector 17. The collector 17 may be a collector with one or more ellipsoidal and/or hyperboloidal reflection surfaces. The illumination radiation 16 may be incident on the at least one reflection surface of the collector 17 with grazing incidence (GI), i.e. at angles of incidence of greater than 45°, or with normal incidence (NI), i.e. at angles of incidence of less than 45°. The collector 17 may be structured and/or coated firstly to optimize its reflectivity for the used radiation and secondly to suppress extraneous light.

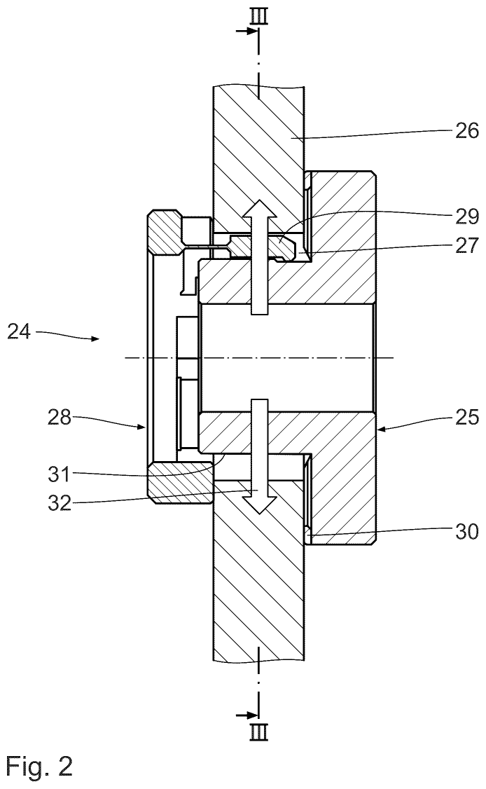

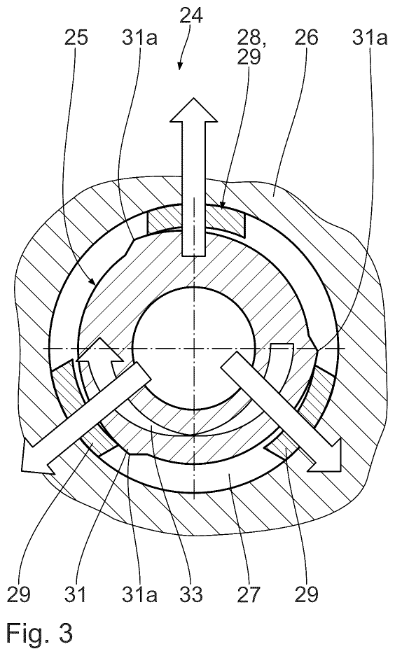

A fastening device serving to fasten additional functional components to the collector 17 will still be explained in detail below with reference to FIGS. 2 and 3.

Downstream of the collector 17, the illumination radiation 16 propagates through an intermediate focus in an intermediate focal plane 18. The intermediate focal plane 18 may represent a separation between a radiation source module, comprising the radiation source 3 and the collector 17, and the illumination optics unit 4.

The illumination optics unit 4 comprises a first facet mirror 19. If the first facet mirror 19 is arranged in a plane of the illumination optics unit 4 which is optically conjugate to the object plane 6, then this facet mirror is also referred to as a field facet mirror. The first facet mirror 19 comprises a multiplicity of individual first facets 20, which are also referred to below as field facets. Only a few of these facets are illustrated in FIG. 1 in exemplary fashion.

The first facets 20 may be in the form of macroscopic facets, for example rectangular facets or facets with an arcuate or partly circular edge contour. The first facets 20 may be in the form of planar facets or alternatively convexly or concavely curved facets.

As is known from DE 10 2008 009 600 A1, for example, the first facets 20 themselves may each also be composed of a multiplicity of individual mirrors, for example a multiplicity of micromirrors. The first facet mirror 19 may for example be in the form of a microelectromechanical system (MEMS system). For details, reference is made to DE 10 2008 009 600 A1.

In the beam path of the illumination optics unit 4, a second facet mirror 21 is disposed downstream of the first facet mirror 19. If the second facet mirror 21 is arranged in a pupil plane of the illumination optics unit 4, it is also referred to as a pupil facet mirror. The second facet mirror 21 may also be arranged at a distance from a pupil plane of the illumination optics unit 4. In this case, the combination of the first facet mirror 19 and the second facet mirror 21 is also referred to as a specular reflector. Specular reflectors are known from US 2006/0132747 A1, EP 1 614 008 B1 and U.S. Pat. No. 6,573,978.

The second facet mirror 21 comprises a plurality of second facets 22. In the case of a pupil facet mirror, the second facets 22 are also referred to as pupil facets.

The second facets 22 may likewise be macroscopic facets, which can for example have a round, rectangular or else hexagonal boundary, or may alternatively be facets composed of micromirrors. In this regard, reference is likewise made to DE 10 2008 009 600 A1.

The second facets 22 may have planar or alternatively convexly or concavely curved reflection surfaces.

The illumination optics unit 4 thus forms a doubly faceted system. This basic principle is also referred to as a fly's eye integrator.

It may be desirable to arrange the second facet mirror 21 not exactly in a plane that is optically conjugate to a pupil plane of the projection optics unit 10. For example, the pupil facet mirror 22 may be arranged at a tilt with respect to a pupil plane in the projection optics unit 7, for example as described in DE 10 2017 220 586 A1.

The individual first facets 20 are imaged into the object field 5 with the aid of the second facet mirror 21 and with the aid of an imaging optical assembly in the form of a transfer optics unit 23.

The transfer optics unit 23 may have exactly one mirror, or alternatively have two or more mirrors, which are arranged one behind the other in the beam path of the illumination optics unit 4. The transfer optics unit may comprise one or two normal-incidence mirrors (NI mirrors) and/or one or two grazing-incidence mirrors (GI mirrors). In the embodiment shown in FIG. 1, the illumination optics unit 4 thus has exactly three mirrors downstream of the collector 17, specifically the transfer optics unit 23, the first facet mirror 19 and the pupil facet mirror 21.

To the extent that the transfer optics unit 23 downstream of the second facet mirror 21 is omitted, the second facet mirror 21 is the last beam shaping mirror or else indeed the last mirror for the illumination radiation 16 in the beam path upstream of the object field 5. An example of an illumination optics unit 4 without a transfer optics unit is disclosed in FIG. 2 of WO 2019/096654 A1.

The imaging of the first facets 20 into the object plane 6 via the second facets 22 or using the second facets 22 and a transfer optics unit 23 is regularly only approximate imaging.

The projection optics unit 10 comprises a plurality of mirrors Mi, which are consecutively numbered in accordance with their arrangement in the beam path of the projection exposure apparatus 1.

In the example illustrated in FIG. 1, the projection optics unit 10 comprises eight mirrors M1 to M8. Alternatives with four, six, ten, twelve or any other number of mirrors Mi are likewise possible. The projection optics unit 10 is an obscured optical unit. The last mirror M8 has a passage opening for the illumination radiation 16. The projection optics unit 10 has an image-side numerical aperture that is greater than 0.4 and may be 0.5, for example. The image-side numerical aperture may be even larger; it may be greater than 0.6 and may be 0.7 or 0.75, for example.

Reflection surfaces of the mirrors Mi may be in the form of free-form surfaces without an axis of rotational symmetry. Alternatively, the reflection surfaces of the mirrors Mi may be designed as aspherical surfaces with exactly one axis of rotational symmetry of the reflection surface shape. Just like the mirrors of the illumination optics unit 4, the mirrors Mi may have highly reflective coatings for the illumination radiation 16. These coatings may be in the form of multilayer coatings, for example with alternating layers of molybdenum and silicon.

The projection optics unit 10 may be embodied in anamorphic fashion. For example, it has different imaging scales βₓ, β_{y} in the x-and y-directions. The two imaging scales βₓ, β_{y} of the projection optics unit 10 can lie at (βₓ, β_{y})=(+/−0.25, +/−0.125). A positive imaging scale β means imaging without image inversion. A negative sign for the imaging scale β means imaging with image inversion.

The projection optics unit 10 leads to a reduction in size with a ratio of 4:1 in the x-direction, i.e. in a direction perpendicular to the scanning direction.

The projection optics unit 10 leads to a reduction in size of 8:1 in the y-direction, i.e. in the scanning direction.

Other imaging scales are likewise possible. Imaging scales with the same signs and the same absolute values in the x-and y-directions, for example with absolute values of 0.125 or 0.25, are also possible.

The number of intermediate image planes in the x-direction and in the y-direction in the beam path between the object field 5 and the image field 11 can be the same or can be different, depending on the embodiment of the projection optics unit 10. Examples of projection optics units with different numbers of such intermediate images in the x and y directions are known from US 2018/0074303 A1.

In each case one of the pupil facets 22 is assigned to exactly one of the field facets 20 for the purpose of forming a respective illumination channel for illuminating the object field 5. For example, this may result in illumination according to the Köhler principle. The far field is decomposed into a multiplicity of object fields 5 with the aid of the field facets 20. The field facets 20 generate a plurality of images of the intermediate focus on the pupil facets 22 respectively assigned thereto.

The field facets 20 are each imaged by an assigned pupil facet 22 onto the reticle 7 in a manner overlaid on one another in order to illuminate the object field 5. The illumination of the object field 5 is for example as homogeneous as possible. It can have a uniformity error of less than 2%. Field uniformity may be achieved by overlaying different illumination channels.

The illumination of the entrance pupil of the projection optical unit 10 may be defined geometrically by way of an arrangement of the pupil facets. The intensity distribution in the entrance pupil of the projection optics unit 10 may be set by selecting the illumination channels, for example the subset of the pupil facets that guide light. This intensity distribution is also referred to as illumination setting or illumination pupil filling fly.

A likewise preferred pupil uniformity in the region of portions of an illumination pupil of the illumination optics unit 4 that are illuminated in a defined manner may be achieved by a redistribution of the illumination channels.

Further aspects and details of the illumination of the object field 5 and for example of the entrance pupil of the projection optics unit 10 are described below.

The projection optics unit 10 may have for example a homocentric entrance pupil. The latter may be accessible. It may also be inaccessible.

The entrance pupil of the projection optics unit 10 generally cannot be illuminated exactly via the pupil facet mirror 21. The aperture rays often do not intersect at a single point in the event of imaging by the projection optics unit 10 that telecentrically images the center of the pupil facet mirror 21 onto the wafer 13. However, it is possible to find an area in which the spacing of the aperture rays, which is determined in pairs, becomes minimal. This area is the entrance pupil or an area conjugate thereto in real space. For example, this area exhibits a finite curvature.

It may be the case that the projection optics unit 10 has different poses of the entrance pupil for the tangential beam path and for the sagittal beam path. In this case, an imaging element, for example an optical component of the transfer optics unit 23, should be provided between the second facet mirror 21 and the reticle 7. With the aid of this optical element, it is possible to take the different poses of the tangential entrance pupil and the sagittal entrance pupil into account.

In the arrangement of the components of the illumination optics unit 4 illustrated in FIG. 1, the pupil facet mirror 21 not is arranged in an area conjugate to the entrance pupil of the projection optics unit 10. It is also arranged at a tilt to the object plane 5. The second facet mirror 21 is furthermore arranged at a tilt with respect to an arrangement plane defined by the first facet mirror 19.

FIGS. 2 and 3 are used to explain in detail the fastening device 24 for fastening a functional component 25 to the collector 17 in a longitudinal sectional illustration. Depending on the embodiment, the functional component 25 may be a mirror, for example also a mirror of an EUV collector, or else, provided the functional component is in the form of a non-optical component, a sensor element or else any other form of a measuring mechanism or a tool for projection lithography.

FIG. 2 shows the fastening device 24 and a substrate body 26 in a section, with the fastening device 24 being shown in longitudinal section. The substrate body may be a mount, a holder or else a frame for the respective optical or else non-optical functional component 25.

The fastening device 24 comprises at least one such a functional component 25, which should be fastened on and/or in the substrate body 26. To this end, the substrate body 26 comprises a receptacle 27, which in the illustration according to FIG. 2 is in the form of a through-bore.

The functional component 25 is held in the receptacle 27 of the substrate body 26 by a fastening component 28. To this end, the fastening component 28 comprises at least one clamping element 29. In the embodiment illustrated in FIGS. 2 and 3, the fastening component 28 has three clamping elements 29 in the form of ribs or lugs which extend around a central axis of the circular receptacle 27 in circumferential direction and which are formed on a main body of the fastening component 28 by way of flexures.

The functional component 25 furthermore comprises a planar functional component bearing surface 30, by which the functional component 25 is placed against the substrate body 26.

The functional component 25 furthermore comprises a curved fastening bearing surface 31, which is placed against the clamping elements 29 of the fastening component 28 so as to be wedged and/or clamped with the latter, in such a way that a form-fitting connection is established between the functional component 25 and the substrate body 26 in a radial direction 32 with respect to a longitudinal axis of the functional component 25.

As may also be gathered from FIG. 2, the main body of the fastening component 28 is arranged on the side of the substrate body 26 opposite the functional component bearing surface 30.

FIG. 2 depicts exactly one clamping element 29 of the fastening component 28. The respective clamping element 29 is prestressed counter to the radial direction 32 toward the center of the receptacle 27 via the associated flexure.

The functional component 25 has a T-shaped longitudinal section. A transverse beam of the T, i.e. the main portion of the T longitudinal section, in this case comprises the functional component bearing surface 30, with which the functional component 25 is placed against the substrate body 26. The portion of the T orthogonal to the transverse beam comprises the fastening bearing surface 31 with a non-constant radius of curvature as outer lateral wall. The radius of curvature of the fastening bearing surface 31 of the functional component 25 becomes periodically larger and smaller in the circumferential direction 33 not illustrated in FIG. 1. In this way, there is a cam-shaped or tooth-shaped fastening bearing surface 31 with cams or teeth 31a in the circumferential direction. In this case, a slope of a radius value gradient of this toothing of the fastening bearing surface 31, as measured in the circumferential direction 33, is constant in regions.

FIG. 3 shows a plane view of the fastening device 24.

FIG. 3 illustrates a fastening component 28 having three clamping elements 29. The three clamping elements 29 are prestressed toward the center of the receptacle 27 counter to the radial direction 32 by the fastening component 28. The clamping elements 29 are at a constant distance from one another in the circumferential direction 33. In relation to the center of the receptacle 27, any two of the clamping elements 29 are arranged at an angle of 120° with respect to each other.

As illustrated in FIG. 2, the toothing of the gearwheel-shaped fastening bearing surface 31 of the functional component 25 comprises three cams or teeth 31a. The number of teeth 31a of the fastening bearing surface 31 matches the number of clamping elements 29 of the fastening component. There may be more clamping elements 29 and correspondingly more teeth of the fastening bearing surface 31 in other embodiments of the disclosure. A greater number of teeth of the fastening bearing surface 31 accordingly leads to a greater gradient of the fastening bearing surface 31 in the circumferential direction 33.

In FIG. 2, the functional component 25 is illustrated in a clamped position in relation to the substrate body 26. By rotating the functional component 25 in the circumferential direction 33 it is possible to transfer the functional component 25 into a non-clamped position. The functional component 25 can be replaced in a non-clamped position.

In the clamped position, the functional component 25 is arranged so as to be centered with respect to the receptacle 27 of the substrate body 26. For example, the geometric centroids of the receptacle 27 and of the functional component 25 coincide in the clamped arrangement.

As also illustrated in FIG. 2, the functional component 25 is hollow in its interior. Especially in the axial direction, the cavity of the functional component 25 extends over the entire length of the functional component 25 such that the fastening of the functional component 25 to the substrate body 26 does not seal the receptacle 27 in the form of a through-bore.

In order to produce a microstructured or nanostructured component, the projection exposure apparatus 1 is used as follows. Initially, the reticle 7 and the wafer 13 are provided. Subsequently, a structure on the reticle 7 is projected onto a light-sensitive layer of the wafer 13 with the aid of the projection exposure apparatus 1. Then a microstructure or nanostructure on the wafer 13, and hence the microstructured component, is generated by developing the light-sensitive layer. This component is a semiconductor component, for example a microchip, for example a memory chip.

What is claimed is:

1. A fastening device, comprising:
a functional component insertable into a receptacle of a substrate body; and
a fastening component comprising first and second clamping elements configured to establish a form-fitting connection between: i) the fastening component and the functional component; and ii) the fastening component and the substrate body,
wherein a volumetric coefficient of thermal expansion of the functional component is less than a volumetric coefficient of thermal expansion of the fastening component.

2. The fastening device of claim 1, wherein the functional component comprises a functional component bearing surface configured to place the functional component against the substrate body.

3. The fastening device of claim 1, wherein the fastening component is configured to receive the functional component in a centered position in the receptacle of the substrate body.

4. The fastening device of claim 1, wherein the functional component comprises a curved fastening bearing surface with a non-constant radius of curvature, wherein the curved fastening bearing surface is configured to place the functional component against the first clamping element.

5. The fastening device of claim 4, wherein the curved fastening bearing surface comprises a toothing in a circumferential direction, and/or wherein the first and second clamping elements comprise ribs extending opposite to a radial direction.

6. The fastening device of claim 4, wherein:
the curved fastening bearing surface comprises a toothing in a circumferential direction, and the toothing has a constant gradient in the circumferential direction; and/or
the first and second clamping elements comprise ribs extending opposite to a radial direction, and the ribs have a constant gradient in the circumferential direction.

7. The fastening device of claim 1, wherein the functional component is configured to be wedged and/or clamped with the fastening component.

8. The fastening device of claim 1, wherein the substrate body comprises a constituent part of the fastening device, and the substrate body comprises a receptacle for the functional component.

9. The fastening device of claim 8, wherein the volumetric coefficient of thermal expansion of the functional component is less than a volumetric coefficient of thermal expansion of the substrate body.

10. The fastening device of claim 1, wherein the functional component comprises an optical component, a sensor element, a projection lithography measuring mechanism, or a projection lithography tool.

11. The fastening device of claim 10, wherein the substrate body comprises a mount or a frame for the functional component.

12. The fastening device of claim 11, wherein the substrate body comprises a mount or a frame for the functional component.

13. The fastening device of claim 1, wherein the functional component comprises a mirror of a collector.

14. The fastening device of claim 13, wherein the substrate body comprises a mount or a frame for the mirror.

15. The fastening device of claim 14, wherein the mirror comprises an EUV mirror.

16. An apparatus, comprising:
a substrate comprising a substrate body which comprises a receptacle; and
a fastening device, comprising:
a functional component insertable into the receptacle of the substrate body; and
a fastening component comprising first and second clamping elements configured to establish a form-fitting connection between: i) the fastening component and the functional component; and ii) the fastening component and the substrate body,
wherein a volumetric coefficient of thermal expansion of the functional component is less than a volumetric coefficient of thermal expansion of the fastening component mirror apparatus.

17. The apparatus of claim 16, wherein the functional component comprises a mirror of an EUV collector.

18. The apparatus of claim 17, wherein the substrate body comprises a mount or a frame for the mirror.

19. An optical system, comprising:
an illumination source;
a substrate comprising a substrate body which comprises a receptacle; and
a fastening device, comprising:
a functional component insertable into the receptacle of the substrate body; and
a fastening component comprising first and second clamping elements configured to establish a form-fitting connection between: i) the fastening component and the functional component; and ii) the fastening component and the substrate body,
wherein a volumetric coefficient of thermal expansion of the functional component is less than a volumetric coefficient of thermal expansion of the fastening component mirror apparatus.

20. An apparatus, comprising:
an optical system according to claim 19, wherein the apparatus is a projection exposure apparatus.
